(19) United States
(12) Patent Application Publication
(10) Pub. No.: US 2014/0076395 A1
(43) Pub. Date: Mar. 20, 2014

(54) POLYMER SOCKETS FOR BACK-CONTACT PHOTOVOLTAIC CELLS

(71) Applicant: PETROS DAFNIOTIS, GENEVA (CH)

(72) Inventor: PETROS DAFNIOTIS, GENEVA (CH)

(73) Assignee: E I DU PONT DE NEMOURS AND COMPANY, Wilmington, DE (US)

(21) Appl. No.: 14/031,475

(22) Filed: Sep. 19, 2013

Related U.S. Application Data
(60) Provisional application No. 61/703,436, filed on Sep. 20, 2012.

(51) Int. Cl. H01L 31/0224

(52) U.S. Cl. CPC H01L 31/02245
USPC 136/256

(57) ABSTRACT

Polymer sockets are provide for accepting and electrically connecting a back-contact photovoltaic cells having at least one set of linearly arranged backface emitter contacts and at least one set of linearly arranged backface collector contacts. A process for electrically connecting the polymer sockets to each other and to back-contact photovoltaic cells is also provided.

### FIELD OF THE INVENTION

The present invention relates to polymer sockets for back-contact photovoltaic cells and a process for the manufacture thereof.

### BACKGROUND OF THE INVENTION

Photovoltaic cells, sometimes called solar cells or photoactive cells, can convert light, such as sunlight, into electrical energy.

In practice, a plurality of photovoltaic cells is electrically connected together in series or in parallel to form an array of photovoltaic cells which can be incorporated into a photovoltaic module.

In order to increase the voltage delivered by individual photoactive cells to a suitable level, the cells are conventionally connected in series.

A serial connection between the cells of a module can be achieved by connecting the emitter contact of one photovoltaic cell to the collector contact of the next (adjacent) cell, usually by soldering an electrical conductor such as wire, tape or ribbon to the contacts of the adjacent cell.

In most of today's photovoltaic modules, the photovoltaic cells that convert light into electrical energy are H-type cells, in which the emitter contacts and collector contacts are located on opposite sides of the cells. The emitter contacts are located on the front surface, i.e. the surface exposed to the sunlight, whereas the collector contacts are on the back side. FIG. 1A shows the frontface of an H-type photovoltaic cell E having two emitter contacts (D1, D2), also known as emitter bus bars. FIG. 1B shows the backface of an H-type photovoltaic cell E having two collector contacts (F1, F1), also known as collector bus bars. A skilled person will recognize that emitter contacts and collector contacts are of opposite polarity.

The electrical conductors connecting two cells are soldered such that the front emitter contacts of one photovoltaic cell are connected with one or more back collector contacts of the adjacent photovoltaic cell. On an industrial scale, the electrical conductors are applied to the cell contacts by way of automated soldering equipment (so-called “tabber-stringer”).

However, when soldered to the front emitter contacts, the electrical conductors cover a portion of the available photovoltaic surface of the cell, which in turn reduces the amount of electrical energy that can be produced by the cell.

New cell types have been developed in which the emitter contacts have been moved from the front face to the back face of the photovoltaic cell in order to free up an additional portion of front surface and increase the amount of electrical energy that can be produced by the cell.

Such photovoltaic cells, in which both emitter and collector contacts are located on the back side of the cell, are known under the common designation “back-contact cells”, which designation encompasses metallization wrap-through (MWT) cells, back-junction (BJ) cells, integrated back contact (IBC) cells and emitter wrap-through (EWT) cells.

Moving from traditional H-type cells having front emitter contacts to back-contact cells having back emitter contacts requires drastic changes in the structure of the photovoltaic module itself, such as for example a complete redesign of the electrical connections between the cells. Concurrently, these structural changes in the photovoltaic module also require a redesign of the manufacturing equipment as well as changes in the module manufacturing method.

WO2006/123938 describes a method of contacting MWT cells by tabbing and stringing. However, the proposed method requires the use of extensive amounts of an insulating material, which is economically discouraging. Furthermore, applying significant amounts of insulating material as well as the electrical conductors on the rear side of a cell creates local unevenness that will warp the cell during the lamination step of module production. The warpage induces mechanical strains in the cell, which results in a lessened degree of efficiency, and also results in the formation of cracks.

The above described changes make the purchase of new manufacturing equipment inevitable for a module manufacturer desiring to use back-contact cells, which presents a considerable economic hurdle for the adoption of back-contact cells in photovoltaic modules. It would therefore be desirable to provide for a means that allows the manufacturing of photovoltaic modules incorporating back-contact cells, but without the need of entirely replacing or considerably altering existing manufacturing equipment and thus make the change more economically feasible.

### SUMMARY OF THE INVENTION

The present invention provides for a polymer socket for accepting and electrically connecting a back-contact photovoltaic cell having at least one set of linearly arranged backface emitter contacts and at least one set of linearly arranged backface collector contacts. The polymer socket comprises a planar, electrically insulating polymer substrate comprising perforations coinciding with the backface emitter contacts, and at least one electrical conductor being collinear with the perforations of the planar polymer substrate coinciding with the at least one set of linearly arranged backface emitter contacts. The at least one electrical conductor is adhered to the backface of the planar polymer substrate.

In another aspect, the present invention provides for an assembly of the dislosed polymer socket and a back-contact photovoltaic cell. Stated alternatively, it provides for a polymer socket for accepting and electrically connecting a back-contact photovoltaic cell having at least one set of linearly arranged backface emitter contacts and at least one set of linearly arranged backface collector contacts, the polymer socket comprising a planar, electrically insulating polymer substrate comprising perforations coinciding with the backface emitter contacts, and at least one electrical conductor being collinear with the perforations of the planar polymer substrate coinciding with the at least one set of linearly arranged backface emitter contacts. The at least one electrical conductor is adhered to the backface of the planar polymer substrate. The polymer socket accepts and electrically connects a back-contact photovoltaic cell.

The present invention further provides for a process for manufacturing a polymer socket for accepting and electrically connecting a back-contact photovoltaic cell having at least one set of linearly arranged backface emitter contacts and at least one set of linearly arranged backface collector contacts. The process comprises the steps of, in this order, (a) forming perforations in a planar, electrically insulating polymer substrate such that the perforations coincide with the backface emitter contacts, and (b) adhering at least one electrical conductor to the backface of the planar, electrically insulating polymer substrate such that said conductor is collinear with the perforations coinciding with the at least one set of linearly arranged backface emitter contacts.

### BRIEF DESCRIPTION OF THE DRAWINGS

FIG. 1A shows the frontface of an H-type photovoltaic cell.

FIG. 1B shows the backface of an H-type photovoltaic cell.

FIG. 2 shows the frontface of a MWT photovoltaic cell.

FIG. 3 shows the backface of a MWT photovoltaic cell of FIG. 2.

FIG. 4 shows an exploded view of a plurality of MWT photovoltaic cells and a plurality of polymeric sockets electrically interconnected to form interconnected polymer sockets and photovoltaic cells.

FIG. 5A shows the frontface of a planar, electrically insulating polymer substrate of a polymeric socket.

FIG. 5B shows a cross-sectional side view of the electrically insulating polymer substrate of FIG. 5A.

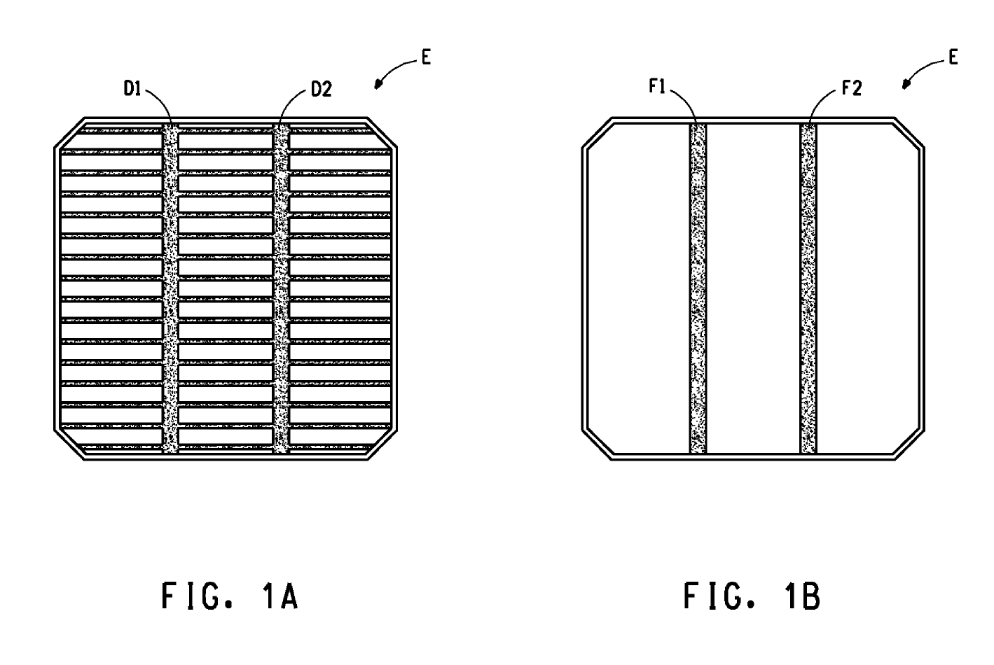

### DETAILED DESCRIPTION

For the purpose of the present disclosure, the term “backface” or “back” denotes the surface of a photovoltaic cell in a photovoltaic module, or of any other planar element in a photovoltaic module, such as in particular the polymer socket of the present invention, which faces away from incident light, i.e. which faces towards the back sheet of the photovoltaic module.

For the purpose of the present disclosure, the term “frontface” or “front” denotes the surface of a photovoltaic cell in a photovoltaic module, or of any other planar element in a photovoltaic module, such as in particular the polymer socket of the present invention, which faces towards incident light, i.e. which faces away from the back sheet and towards the front sheet of the photovoltaic module.

For the purpose of the present disclosure, the term “light” means any type of electromagnetic radiation that can be converted into electric energy by a photovoltaic cell.

For the purpose of the present disclosure, the terms “photoactive” and “photovoltaic” may be used interchangeably and refer to the property of converting radiant energy (e.g., light) into electrical energy.

For the purpose of the present disclosure, the terms “photovoltaic cell” or “photoactive cell” means an electronic device that can convert electromagnetic radiation (e.g., light) into an electrical signal. A photovoltaic cell includes a photoactive material layer that may be an organic or inorganic semiconductor material that is capable of absorbing radiation and converting it into electrical energy. The terms “photovoltaic cell” or “photoactive cell” are used herein to include solar cells with any types of photoactive layers including crystalline silicon, amorphous silicon, cadmium telluride, and copper indium gallium selenide (GIGS) photoactive layers.

For the purpose of the present disclosure, the term “photovoltaic module” (also “module” for short) means any electronic device having at least one photovoltaic cell.

For the purpose of the present disclosure, the term “encapsulant layer” refers to a layer of material that is designed to protect the photoactive cells from degradation caused by chemical and/or mechanical stress.

For the purpose of the present disclosure, the term “front encapsulant layer” refers to an encapsulant layer that is located between the frontface of a photoactive cell and the front sheet of the module. For the purpose of the present disclosure, the term “back encapsulant layer” refers to an encapsulant layer that is located between the backface of a photoactive cell and the back sheet of the module.

For the purpose of the present disclosure, the term “ionomer” means and denotes a thermoplastic resin containing both covalent and ionic bonds derivable from ethylene copolymers. Ionomers may be obtained by partial neutralization of ethylene-methacrylic acid copolymers or ethylene-acrylic acid copolymers with inorganic bases having cations of elements from Groups I, II, or III of the Periodic table, notably, sodium, aluminum, lithium, magnesium, and barium may be used, or transition metals such as zinc. The term “ionomer” and the resins identified thereby are well known in the art, as evidenced by Richard W. Rees, “Ionic Bonding In Thermoplastic Resins”, DuPont Innovation, 1971, 2(2), pp. 1-4, and Richard W. Rees, “Physical Properties And Structural Features Of Surlyn Ionomer Resins”, Polyelectrolytes, 1976, C, 177-197.

For the purpose of the present disclosure, the term “emitter contact” means and denotes an electrical contact connecting the emitter of a photovoltaic cell to an electrical conductor. In the case of a back-contact photovoltaic cell such as MWT cells, the emitter contacts are the so-called “vias”, or “back emitter contacts”, located on the backface of the cell.

For the purpose of the present disclosure, the term “collector contact” means and denotes an electrical contact connecting the collector of a photovoltaic cell to an electrical conductor. In the case of a back-contact photovoltaic cell such as MWT cells, the collector contacts are located on the backface of the cell.

For the purpose of the present disclosure, the term “collinear” refers to a collinear relationship, when viewed along the direction normal to the plane defined by the polymer substrate of the polymer socket.

For the purpose of the present disclosure, the term “linearly arranged contact set” refers to a plurality of the same type of contacts (either collector or emitter) arranged in-line.

A planar, electrically insulating polymer substrate provides an effective solution by acting like a selective grid that allows electrical contacts in some regions while being electrically insulating in others. The present invention represents an improvement over existing cumbersome solutions for electrically connecting back-contact photovoltaic cells, such as for example dielectric coatings requiring selective application, for example by screen printing, to the backface of a back-contact cell to electrically insulate certain regions of the back-contact cell.

Disclosed herein is a polymer socket for accepting and electrically connecting a back-contact photovoltaic cell having at least one set of linearly arranged backface emitter contacts and at least one set of linearly arranged backface collector contacts. The polymer socket comprises a planar, electrically insulating polymer substrate comprising perforations coinciding with the backface emitter contacts. At least one electrical conductor is collinear with the perforations of the planar polymer substrate and coincides with the at least one set of linearly arranged backface emitter contacts. The at least one electrical conductor is adhered to the backface of the planar polymer substrate.

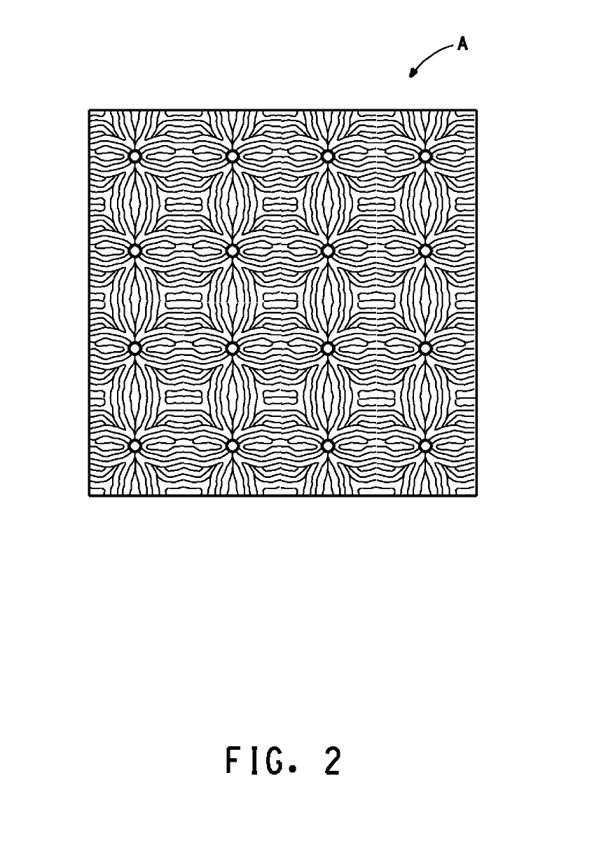

FIG. 2 shows the frontface of a MWT photovoltaic cell A. The lines that can be seen on the surface of the MWT back-contact photovoltaic cell are emitter contact lines comprised of a conductive material such as silver. The lines connect to a pluralitiy of spaced electrical vias that can be seen in FIG. 2 and which connect through the photovoltaic cell to backface emitter contacts on the back of the cell.

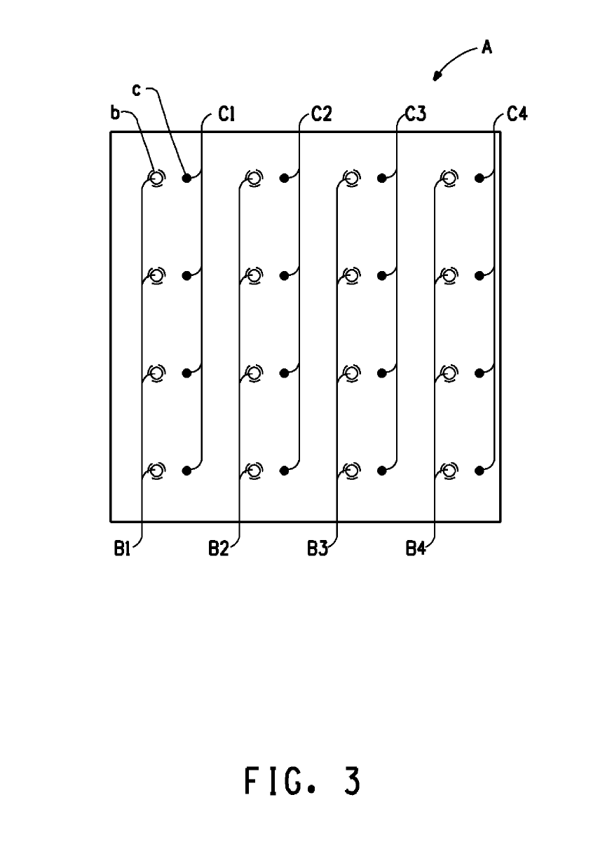

FIG. 3 shows the backface of a MWT photovoltaic cell A having four sets (B1, B2, B3, B4) of linearly arranged backface emitter contacts b and four sets (C1, C2, C3, C4) of linearly arranged backface collector contacts c.

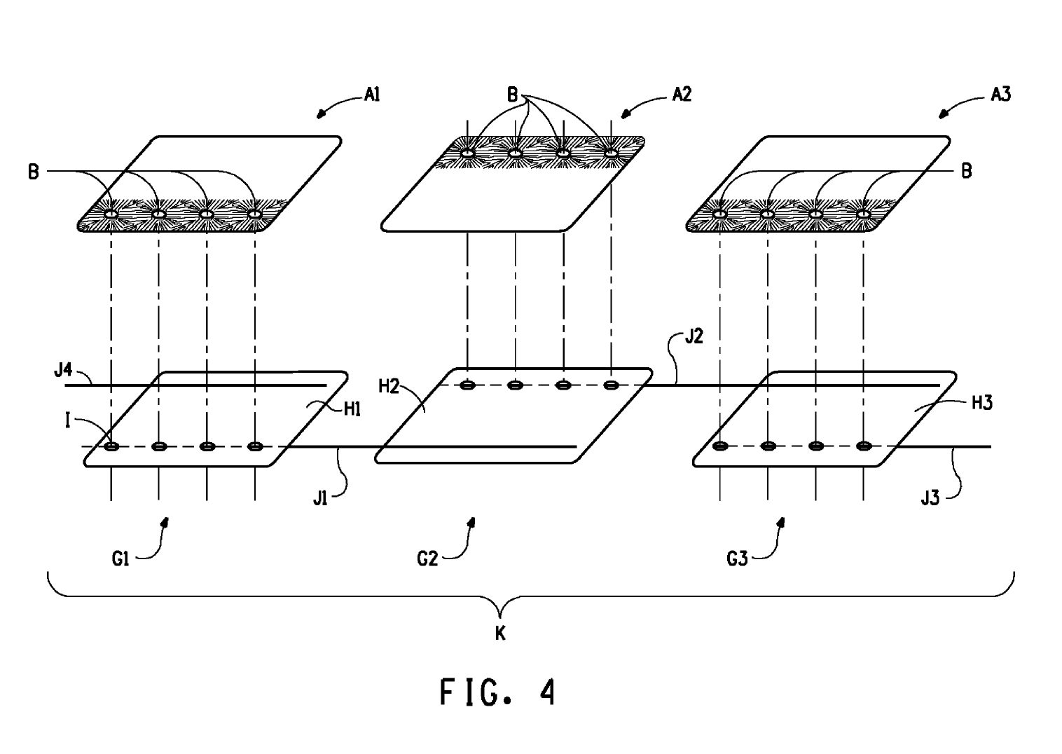

FIG. 4 shows an illustrative embodiment with a plurality of MWT photovoltaic cells (A1, A2, A3) of a back-contact photovoltaic module. A plurality of polymeric sockets (G1, G2, G3) comprising planar, electrically insulating polymer substrates (H1, H2, H3) are provided on the back side of each of the MWT cells. The polymeric sockets (G1, G2, G3) have perforations I coinciding with a set of linearly arranged backface emitter contacts (B) of the MWT photovoltaic cells to be accepted by the corresponding sockets.

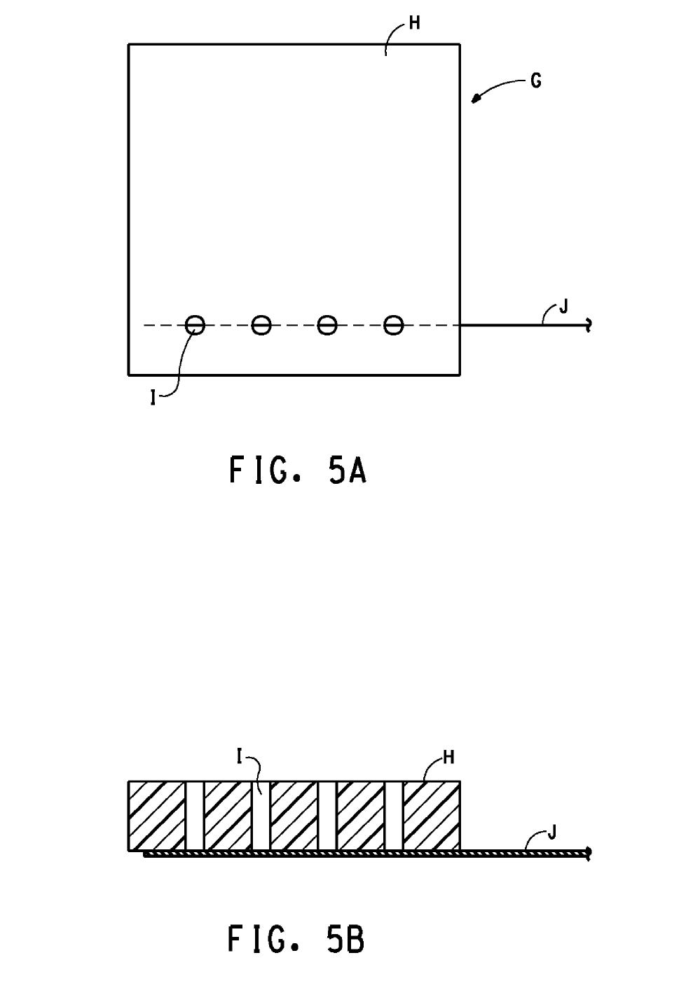

FIG. 5A shows the frontface of a planar, electrically insulating polymer substrate H of a polymeric socket G having perforations I to coincide with a row of linearly arranged backface emitter contacts of a MWT photovoltaic cell to be accepted by the socket. An electrical conductor J is collinear with the perforations I and is adhered to the backface of the polymer substrate. FIG. 5B shows a cross-sectional side view of the electrically insulating polymer substrate H along the electrical conductor J. The substrate has perforations I, and the conductor J is shown adhered to the backface of the polymer substrate H.

As shown in FIG. 4, the polymer substrates and MWT cells are interconnected by the electrical conductors (J1, J2, J3, J4) to form a concatenation K of interconnected polymer sockets. The backface emitter contacts of a first cell A1 are electrically connected to the conductor J1 through the perforations I in the polymer substrate. The backface emitter contacts of a first cell A1 are electrically connected to the backface collector contacts of the adjacent cell A2 via the conductor J1. The conductor is collinear with the perforations I coinciding with the set of linearly arranged backface emitter contacts of the MWT cells and the set of linearly arranged backface collector contacts of the MWT photovoltaic cell to be accepted and electrically connected by the adjacent polymer socket. For illustrative purposes, FIG. 4 shows photovoltaic MWT cells with just one row of emitter contacts and just one row of collector contacts, but it is contemplated that back-contact photovoltaic cells with multiple rows of emitter contacts and collector contacts, like the cell shown in FIG. 3, can be electrically connected with polymeric sockets having a corresponding number of electrical conductors.

The polymer socket for accepting and electrically connecting a back-contact photovoltaic cell may have any suitable shape. Suitable shapes of the polymer socket include regular geometric shapes such as square, rectangular, triangular or lozenge.

The shape and size of the planar, electrically insulating polymer substrate of the polymer socket may preferably correspond to or extend beyond the shape and size of the back-contact photovoltaic cell to be accepted and electrically connected by the polymer socket. More preferably, the shape and size of the planar, electrically insulating polymer substrate extends of from, for example, 0.5 mm to 5 mm beyond the edges of the back-contact photovoltaic cell to be accepted and electrically connected by the polymer socket. The thickness of the polymer substrate may be of from, for example, 50 μm to 500 μm, more preferably of from 50 μm to 200 μm.

The back-contact cells useful in the present invention may be chosen among MWT cells, BJ cells, IBC cells and EWT cells, and are preferably MWT cells. The back-contact cells may be back-contact cells having the backface emitter contacts and the backface collector contacts coated with an electrically conductive soldering composition. Examples of electrically conductive soldering compositions are tin-, tin-lead-, or tin-lead-silver-based soldering compositions.

Preferably, the back-contact cells useful in the present invention may be chosen among “symmetrical” back-contact cells, i.e. back-contact cells having the same number of linearly arranged backface emitter contact sets and of linearly arranged backface collector contact sets. More preferably, in the “symmetrical” back-contact cells, the sets of linearly arranged backface emitter contacts and the sets of linearly arranged backface collector contacts alternate.

FIG. 3 shows a symmetrical back-contact cell in which the sets of linearly arranged backface emitter contacts and backface collector contacts alternate, and in which the sets of linearly arranged backface collector contacts and backface emitters contacts are parallel to each other.

In an embodiment, the planar, electrically insulating polymer substrate of the polymer socket according to the present invention exhibits the behavior of an elastomeric thermoplastic polymer. In the embodiment, it is preferred, that the planar polymer substrate of the polymer socket of the present invention comprises or consists of at least one elastomeric thermoplastic polymer. Suitable elastomeric thermoplastic polymers may be chosen among polymers having a melting temperature (Tₘ) in excess of the temperature applied in the lamination process step of the photovoltaic module manufacturing process. The elastomeric thermoplastic polymers may be chosen, for example among styrenic block copolymers, polyolefin blends, elastomeric alloys such as engineering thermoplastic vulcanizates (ETPVs), ionomers, thermoplastic polyurethanes, thermoplastic copolyesters and thermoplastic polyamides. Preferably, the planar, electrically insulating polymer substrate comprises a styrenic block copolymer such as styrene-butadiene-styrene block copolymer (SBS), styrene-isoprene-styrene block copolymer (SIS), styrene-ethylene/butylene-styrene block copolymer (SEBS) and styrene-ethylene/propylene-styrene block copolymer (SEPS) or thermoplastic copolyester such as polyester-polyether copolymer.

The planar, electrically insulating polymer substrate of the polymer socket according to the present invention may be obtainable, for example, by injection molding the polymer (e.g. elastomeric thermoplastic polymer) into the desired shape, by cutting out the desired shape from a sheet of polymer (e.g. elastomeric thermoplastic polymer), or by laminating together different layers of polymer (e.g. elastomeric thermoplastic polymer).

The planar, electrically insulating polymer substrate of the polymer socket according to the present invention comprises perforations coinciding with the backface emitter contacts of the back-contact photovoltaic cell to be accepted and electrically connected by the polymer socket comprising the substrate. The perforations may be of any shape such as round, oval or rectangular.

The perforations in the planar, electrically insulating polymer substrate coincide with the backface emitter contacts of the back-contact cell to be accepted and electrically connected by the polymer socket. Thus, the perforations make it possible to establish an electrical contact between backface emitter contacts of the back-contact cell and the at least one electrical conductor adhered to the backface of the planar, electrically insulating polymer substrate by enabling, for example, a soldering connection to be made between the conductor and the emitter contact through said perforations. Conversely, the at least one electrical conductor is electrically insulated from the back-contact cell by the planar, electrically insulating polymer substrate where the polymer substrate is unperforated.

In the case where the electrical contact between backface emitter contacts of the back-contact cell and the at least one electrical conductor adhered to the backface of the planar, electrically insulating polymer substrate is made by soldering connection through the perforations, the soldering may be achieved by methods known in the art of phovoltaics, such as for example induction heating, sonic vibration heating or thermosonic vibration heating, press heating, heated rolls, heated pins or infra-red heating. In the case where soldering is achieved by heated rolls, the rolls are preferably dented such that the dents push the at least one electrical conductor through the perforations of the planar, electrically insulating polymer substrate, such that an electrical contact between the at least one set of linearly arranged backface emitter contacts of the back-contact cell and the at least one electrical conductor is achieved.

In a preferred embodiment, the planar, electrically insulating polymer substrate further comprises perforations coinciding with at least one set of linearly arranged backface collector contacts of the back-contact photovoltaic cell to be accepted and electrically connected by the polymer socket.

The at least one electrical conductor may be of any electrically conductive material such as for example, copper, iron, aluminum, tin, silver, gold, and alloys thereof. Preferably, the at least one electrical conductor comprises a copper or aluminum core surrounded by an electrically conductive soldering composition. Examples of electrically conductive soldering compositions are tin-, tin-lead-, or tin-lead-silver-based soldering compositions. The at least one electrical conductor may be in the form of, for example, a flattened wire or ribbon, round wire, printed circuit board (PCB), and preferably is in the form of a flattened wire.

The at least one electrical conductor is collinear with the at least one set of linearly arranged backface emitter contacts of the back-contact cell to be accepted and electrically connected, and also with the perforations of the planar polymer substrate coinciding with the at least one set of linearly arranged backface emitter contacts. Thus, the at least one set of linearly arranged backface emitter contacts can be electrically connected to the electrical conductor through the perforations, for example by soldering.

The at least one electrical conductor is located on the backface of the planar polymer substrate, i.e. it is separated, and electrically insulated, from the back-contact photovoltaic cell located on the frontface of the polymer substrate by the polymer substrate itself where the polymer substrate is unperforated. The at least one electrical conductor may be adhered to the backface of the planar polymer substrate by a suitable adhesive, or may be adhered to the backface of the planar polymer substrate by heating the electrical conductor to a temperature above the melting temperature of the polymer (e.g. elastomeric thermoplastic polymer) of the planar polymer substrate and pressing the electrical conductor against the backface of the planar polymer substrate until the temperature of the conductor drops below the melting temperature of the polymer of the planar polymer substrate, and releasing the previously applied pressure.

In an embodiment, the polymer socket accepts and electrically connects a back-contact photovoltaic cell having at least one set of linearly arranged backface emitter contacts and at least one set of linearly arranged backface collector contacts, to form an assembly.

According to the present invention, the process for manufacturing a polymer socket for accepting and electrically connecting a back-contact photovoltaic cell having at least one set of linearly arranged backface emitter contacts and at least one set of linearly arranged backface collector contacts can be carried out manually or using an automatic equipment.

The perforations in the planar, electrically insulating polymer substrate may be formed by drilling, punching or locally melting the planar, electrically insulating polymer substrate such that the perforations coincide with the backface emitter contacts of the back-contact photovoltaic cell to be accepted and electrically connected by the polymer socket. Preferably, the perforations in the planar, electrically insulating polymer substrate are created by punching.

In one embodiment, the manufacturing process may further comprise the step of forming additional perforations in the planar, electrically insulating polymer substrate such that the additional perforations coincide with at least one set of backface collector contacts of the back-contact photovoltaic cell to be accepted and electrically connected by the polymer socket.

The at least one electrical conductor may be adhered to the backface of the planar, electrically insulating polymer substrate such that said conductor is collinear with the perforations of the planar polymer substrate coinciding with at least one set of linearly arranged backface emitter contacts.

The at least one electrical conductor may be adhered to the backface of the planar, electrically insulating polymer substrate by heating the conductor to a temperature above the melting temperature of the polymer (e.g. elastomeric thermoplastic polymer) of the planar polymer substrate and by pressing the electrical conductor against the backface of the planar polymer substrate until the temperature of the conductor drops below the melting temperature of the polymer of the planar polymer substrate, and then releasing the previously applied pressure.

The heating of the at least one electrical conductor may be achieved by methods known in the art of phovoltaic applications, such as for example induction heating, press heating, sonic vibration heating or thermosonic vibration heating, heated rolls, heated pins, or infra-red heating.

Suitable automatic equipment to adhere the at least one electrical conductor to the backface of the planar, electrically insulating polymer substrate may be a so-called “tabber-stringer” that has been modified to process the planar, electrically insulating polymer substrate.

Conventionally, tabber-stringers are used to string together photovoltaic cells, or so-called “H cells”. The tabbing unit generally serves to place and orient the photovoltaic cells, before the stringing unit strings the photovoltaic cells together with electrical conductor(s) by first adhering the electrical conductor(s) to the backface contacts of a first H cell and then adhering said electrical conductor to the frontface contacts of the next H cell in line.

A person skilled in the art of automatic equipment for tab-stringing together photovoltaic cells will be able to modify a conventional tabber-stringer such that it strings together the planar polymer substrates instead of photovoltaic cells by replacing the photovoltaic cells in the tabber-stringer with the planar, electrically insulating polymer substrate.

In one embodiment, the process according to the present invention further comprises the steps of (c) positioning a back-contact photovoltaic cell on the frontface of the planar, electrically insulating polymer substrate, and (d) electrically connecting the at least one set of linearly arranged backface emitter contacts of the cell to the at least one electrical conductor through the perforations coinciding with the at least one set of linearly arranged backface emitter contacts. Preferably, the electrical connection is made by soldering.

1. A polymer socket for accepting and electrically connecting a back-contact photovoltaic cell having at least one set of linearly arranged backface emitter contacts and at least one set of linearly arranged backface collector contacts, comprising
a. a planar, electrically insulating polymer substrate comprising perforations coinciding with the backface emitter contacts of the back-contact photovoltaic cell to be accepted and electrically connected by the polymer socket, said planar polymer substrate having a frontface and backface on opposite sides of the substrate, the frontface being on the side of the substrate on which the back-contact photovoltaic cell is to be accepted and electrically connected by the polymer socket, said planar polymer substrate having a shape and size that substantially corresponds to the shape and size of the back-contact photovoltaic cell to be accepted and electrically connected by the polymer socket, and
b. a first electrical conductor being collinear with the perforations of the planar polymer substrate coinciding with the at least one set of linearly arranged backface emitter contacts of the back-contact photovoltaic cell to be accepted and electrically connected by the polymer socket, wherein the first electrical conductor is adhered to the backface of the planar polymer substrate, and
c. a second electrical conductor being collinear the at least one set of linearly arranged backface collector contacts of the back-contact photovoltaic cell to be accepted and electrically connected by the polymer socket, wherein the second electrical conductor is adhered to the frontface of the planar polymer substrate.

2. The polymer socket of claim 1 comprising additional perforations coinciding with the backface collector contacts.

3. The polymer socket according to claim 1 any preceding claim, wherein the planar polymer substrate comprises or consists of at least one elastomeric thermoplastic polymer.

4. The polymer socket according to claim 3, wherein the at least one elastomeric thermoplastic polymer is a polyester polyether copolymer.

5. An assembly comprising a polymer socket according to claim 1 any preceding claim wherein the polymer socket has accepted and electrically connected a back-contact photovoltaic cell.

6. (canceled)

7. (canceled)

8. (canceled)

9. (canceled)

10. (canceled)

11. (canceled)

12. The polymer socket according to claim 3, wherein the at least one elastomeric thermoplastic polymer is a styrenic block copolymer.

13. The assembly according to claim 5 wherein the polymer substrate has edges that extend no more than 5 mm beyond the edges of the back-contact photovoltaic cell accepted and electrically connected by the polymer socket.

14. The assembly according to claim 13 wherein the polymer substrate has edges that extend at least 0.5 mm beyond the edges of the back-contact photovoltaic cell accepted and electrically connected by the polymer socket.
